(19) United States
(12) Patent Application Publication
(10) Pub. No.: US 2008/0174019 A1
(43) Pub. Date: Jul. 24, 2008

(54) Semiconductor device and method for manufacturing the same

(75) Inventor: Sang Wook Ryu, Cheongjoo-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu HiTek Co., Ltd.

(21) Appl. No.: 11/980,552

(22) Filed: Oct. 31, 2007

(30) Foreign Application Priority Data
Dec. 11, 2006 (KR) 10-2006-0125281

(51) Int. Cl. H01L 23/522; H01L 21/768

(52) U.S. Cl. 257/751; 438/672; 438/653; 257/E23.145; 257/E21.577

(57) ABSTRACT

A semiconductor device and a method for manufacturing the semiconductor device are provided. The method includes: forming a base interlayer dielectric layer having a first metal wiring on a semiconductor substrate, and a diffusion stop layer on the base interlayer dielectric layer to expose the first metal wiring; forming a first interlayer dielectric layer pattern having a trench and a via hole penetrating through the first interlayer dielectric pattern; forming a second metal wiring in the trench and the via hole and contacting the first metal wiring; exposing an upper portion of the second metal wiring by etching the first interlayer dielectric layer pattern; depositing a silicon nitride film over the first interlayer dielectric layer pattern; and forming a spacer on side walls of the exposed upper portion of the second metal wiring.

The present application claims the benefit of priority under 35 U.S.C. § 119 to Korean Patent Application No. 10-2006-0125281 (filed on Dec. 11, 2006), the entire contents of which are incorporated herein by reference.

### BACKGROUND

The present invention relates to a semiconductor device and a method for manufacturing the semiconductor device.

Recently, rapid advances in integration and speed of semiconductor devices require transistors of a semiconductor device to have a smaller size. As a result, wiring of the semiconductor device becomes finer, and signals carried in the wiring may be delayed or distorted due to the fine wiring. Accordingly, the semiconductor device may be unable to achieve desired high speed.

For this reason, copper wiring has been used in semiconductor devices. The copper wiring has a resistance smaller than that of aluminum wiring or aluminum alloy wiring, which has been widely used as a wiring material for the semiconductor device, and has a high electro-migration (EM) durability.

Copper wiring may be formed by first forming a copper layer and then etching the copper layer. However, copper etching is not easy and surfaces of the copper layer may oxidize in the etching process. Recently, a “damascene process” has been developed in an attempt to resolve this issue.

The damascene process forms a trench and a contact hole in an dielectric layer, and deposits a copper layer on the dielectric layer to fill the trench and the contact hole. Then, the copper layer is planarized by a chemical mechanical polishing (CMP) process, thereby forming a copper wiring inside the trench and the contact hole.

The damascene process can also be used to form a bit line or a word line of the semiconductor device besides metal wiring. In particular, a contact hole (or a via hole) for connecting an upper metal wiring to a lower metal wiring in a multi layer metal wiring can simultaneously be formed when the multi layer metal wiring is formed. Further, the damascene process may remove a step generated between the upper metal wiring and the lower metal wiring, thereby simplifying subsequent processes.

In general, the damascene process may be divided into a via-first method and a trench-first method. Specifically, the via-first method forms a contact hole prior to forming a trench, while the trench-first method forms a trench prior to forming a contact hole.

In the related art, silicon nitride (SiN) or silicon carbide (SiC) is used as a diffusion stop layer in order to improve the electrical reliability of the copper wiring. However, recently, tungsten-cobalt (CoWₓ, where x is a natural number) is used as a diffusion stop layer, because tungsten-cobalt has a lower dielectric constant, a lower copper mobility, and a lower resistance as compared to silicon carbide. At this time, tungsten-cobalt may be formed to be the diffusion stop layer using an electroless plating method.

In particular, since tungsten-cobalt has a smaller optical refractive index than that of silicon nitride or silicon carbide, it may improve an optical transmission rate of the semiconductor device. However, when the diffusion stop layer is formed using the via-first method, as shown in FIG. 1, a copper wiring 1 including a barrier stop layer may be exposed at a portion of a borderless via 2. When a barrier metal layer, such as tantalum (Ta) or tantalum nitride (TiN), is damaged in an etching process for forming a via hole, copper wiring 1 may be exposed in a subsequent process for removing a photoresist layer, thereby being oxidized at region 3.

### SUMMARY

A semiconductor device and a method for manufacturing the semiconductor device are provided. The semiconductor device is manufactured to have an improved electrical property by forming a spacer on sides of a metal wiring in the semiconductor device and by forming a metallic diffusion stop layer on an upper surface of the metal wiring.

In one embodiment, the method includes: forming a base interlayer dielectric layer having a first metal wiring on a semiconductor substrate, and a diffusion stop layer on the base interlayer dielectric layer to expose the first metal wiring; forming a first interlayer dielectric layer pattern having a trench and a via hole penetrating through the first interlayer dielectric pattern; forming a second metal wiring in the trench and the via hole and contacting the first metal wiring; exposing an upper portion of the second metal wiring by etching the first interlayer dielectric layer pattern; depositing a silicon nitride film over the first interlayer dielectric layer pattern; and forming a spacer on side walls of the exposed upper portion of the second metal wiring.

### BRIEF DESCRIPTION OF THE DRAWINGS

FIG. 1 illustrates a conventional process for forming metal wiring, in which copper is exposed and oxidized; and

FIGS. 2 to 6 illustrate a process for forming metal wiring consistent with the present invention.

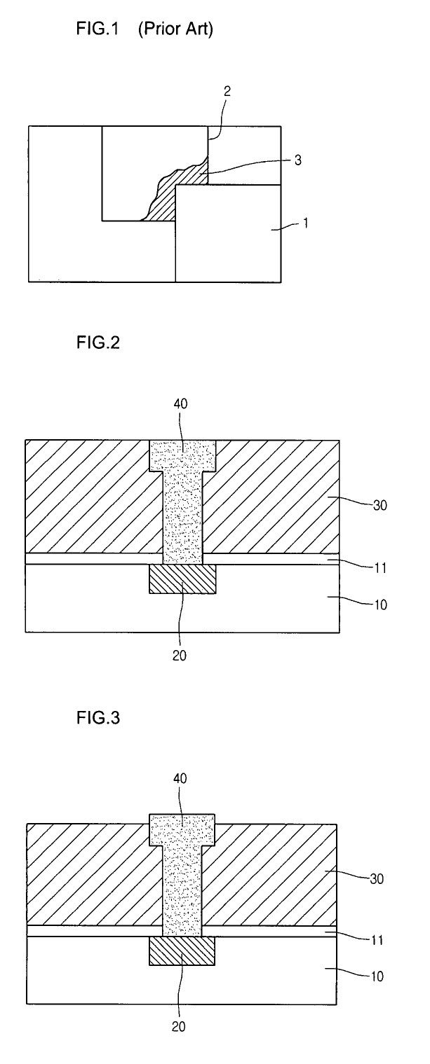

### DETAILED DESCRIPTION

Hereinafter, embodiments consistent with the present invention will be described in detail with reference to the accompanying drawings.

FIGS. 2 to 6 illustrate an exemplary process for forming a metal wiring consistent with the present invention.

Referring to FIG. 2, a base interlayer dielectric layer 10 including a metal wiring 20 is formed on a semiconductor substrate (not shown), and a diffusion stop layer 11 is formed on base interlayer dielectric layer 10 to expose metal wiring 20. In one embodiment, base interlayer dielectric layer 10 may comprise a tetraethoxysilane (TEOS) material. Also, diffusion stop layer 11 may comprise silicon nitride (SiN) or silicon carbide (SiC), and have a thickness of about 300 Å to 1,000 Å.

Thereafter, as shown in FIG. 2, a first interlayer dielectric layer is formed on diffusion stop layer 11 to have a thickness of about 6,000 Å to 18,000 Å. Then, the first interlayer dielectric layer is patterned using a photo-etching process to form a first interlayer dielectric layer pattern 30 having a trench 31 and a via hole 32 penetrating through the first interlayer dielectric layer.

Thereafter, a barrier metal layer and a seed copper layer may be deposited on inner walls of trench 31 and via hole 32. Next, a copper layer filling trench 31 and via hole 32 and contacting metal wiring 20 is formed on first interlayer dielectric layer pattern 30. The copper layer is then polished by a chemical mechanical polishing (CMP) process, thereby forming a copper wiring 40 inside trench 31 and via hole 32 and contacting metal wiring 20.

Thereafter, as shown in FIG. 3, an upper portion of first interlayer dielectric pattern 30 may be wet-etched using, for example, buffered oxide etchant (BOE) solution. As the upper portion of first interlayer dielectric layer pattern 30 is etched and removed, an upper portion of copper wiring 40 is exposed. In one embodiment, first interlayer dielectric layer pattern 30 may be etched by about 50 Å to 2,000 Å. It is appreciated that only a portion of copper wiring 40 needs be exposed as a result of the wet etching process. Although other wet etching solutions may be used, the BOE solution is used in this particular embodiment, because copper has a strong etching resistance against the BOE solution.

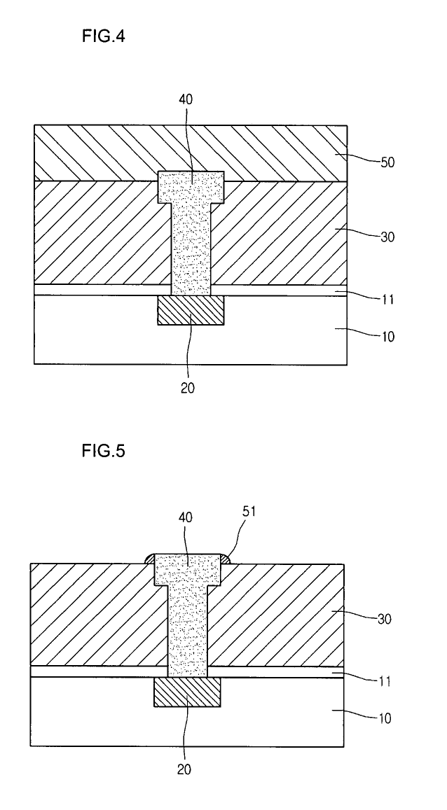

Thereafter, as shown in FIG. 4, a silicon nitride film 50 is deposited over first interlayer dielectric layer pattern 30 where a portion of copper wiring 40 is exposed. In one embodiment, silicon nitride film 50 may be deposited to have a thickness of the exposed portion of copper wiring 40. Therefore, the thickness of silicon nitride film 50 may be about 50 Å to 2,000 Å.

Thereafter, as shown in FIG. 5, silicon nitride film 50 is dry etched using an etching gas, such as fluorohydrocarbons (CₓH_{y}F_{z}, where x, y, and z are natural numbers or zeros), and an inert gas, such as argon (Ar), helium (He), oxygen (O₂), and nitrogen (N₂), so as to form a spacer 51 on sides of the exposed portion of copper wiring 40. Subsequently, the etching reminders and copper reminders may be removed using a fluorine containing solution, such as hydrofluoric acid (HF) and BOE solution, or an amine-based solution, such as NH₂OH, NH₄(OH)₂, etc.

Thereafter, a metallic diffusion stop layer, comprising, for example, tungsten-cobalt (CoW), may be formed on copper wiring 40, the exposed sides of which include spacer 51. Then, a second interlayer dielectric layer is formed to have a thickness of about 6,000 Å to 18,000 Å. Subsequently, the second interlayer dielectric layer is patterned using a photo-etching process to form a second interlayer dielectric layer pattern 60 having a trench 61 and a via hole 62 penetrating through the second interlayer dielectric layer.

Thereafter, a barrier metal layer and a seed copper layer may be deposited on inner walls of trench 61 and via hole 62. Further, a copper layer filling trench 61 and via hole 62 may be formed on second interlayer dielectric layer pattern 60. Then, the copper layer is polished by a chemical mechanical polishing (CMP) process, thereby forming a copper wiring 70 in trench 61 and via hole 62.

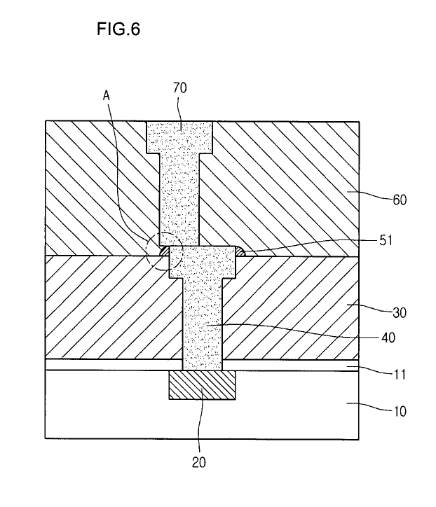

A semiconductor device consistent with the present invention may be manufactured according to the method described above. As shown in FIG. 6, the semiconductor device includes a base interlayer dielectric layer 10 having a copper wiring 20 formed on a semiconductor substrate (not shown), and a diffusion stop layer 11 formed on base interlayer dielectric layer 10.

The semiconductor device further includes a first interlayer dielectric layer pattern 30 having a first trench 31 and a first via hole 32 formed on diffusion stop layer 11, and a copper wiring 40 formed in first trench 31 and first via hole 32 contacting metal wiring 20. In this particular embodiment, copper wiring 40 may be formed to protrude first interlayer dielectric layer pattern 30. More precisely, copper wiring 40 may protrude first interlayer dielectric layer patter 30 by about 50 Å to 2,000 Å.

The semiconductor device further includes a spacer 51 formed on both sides of a portion of copper wiring 40 protruding first interlayer dielectric layer pattern 30, and a metallic diffusion stop layer (not shown) formed on an upper surface of copper wiring 40. In one embodiment, space 51 may comprise silicon nitride, and the metallic diffusion stop layer may comprise tungsten-cobalt (CoW).

The semiconductor device further includes a second interlayer dielectric layer pattern 60 having a second trench 61 and a second via hole 62 formed on first interlayer dielectric layer pattern 30, copper wiring 40, and spacer 51, and copper wiring 70 formed in second trench 61 and second via hole 62.

When second trench 61 and second via hole 62 are formed in second interlayer dielectric layer pattern 60, a borderless via may be generated due to a misalignment between first trench 31 and second trench 61. Accordingly, an upper surface of copper wiring 40 may be exposed in the process for forming second interlayer dielectric layer pattern 60. Although the upper surface of copper wiring 40 may be exposed, copper wiring 40 is protected by spacer 51, thus making it possible to prevent copper wiring 40 from being oxidized.

Also, when forming a multi-layer wiring structure, a step may occur between a copper wiring and an interlayer dielectric layer, thus making it possible to easily focus on the copper wiring.

Although embodiments consistent with the present invention have been described in detail, it should be understood that numerous other modifications and variations can be devised by those skilled in the art. More particularly, variations and modifications are possible in the component parts and/or arrangements of the subject combination arrangement. In addition to variations and modifications in the component parts and/or arrangements, alternative uses will also be apparent to those skilled in the art.

What is claimed is:

1. A method for manufacturing a semiconductor device, comprising:
forming a base interlayer dielectric layer having a first metal wiring on a semiconductor substrate, and a diffusion stop layer on the base interlayer dielectric layer to expose the first metal wiring;
forming a first interlayer dielectric layer pattern having a trench and a via hole penetrating through the first interlayer dielectric pattern;
forming a second metal wiring in the trench and the via hole and contacting the first metal wiring;
exposing an upper portion of the second metal wiring by etching the first interlayer dielectric layer pattern;
depositing a silicon nitride film over the first interlayer dielectric layer pattern; and
forming a spacer on side walls of the exposed upper portion of the second metal wiring.

2. The method according to claim 1, wherein the second metal wiring comprises copper.

3. The method according to claim 1, wherein the diffusion stop layer comprises silicon nitride (SiN) or silicon carbide (SiC), and has a thickness of about 300 Å to 1,000 Å.

4. The method according to claim 1, wherein the first interlayer dielectric layer is formed at a thickness of about 6,000 Å to 18,000 Å.

5. The method according to claim 1, wherein exposing the upper surface of the first interlayer dielectric layer pattern comprises wet etching the first interlayer dielectric layer pattern using a buffered oxide etchant (BOE) solution.

6. The method according to claim 1, wherein the first interlayer dielectric layer pattern is etched by about 50 Å to 2,000 Å.

7. The method according to claim 1, wherein forming the spacer comprises depositing a silicon nitride film over the first interlayer dielectric layer pattern, and etching the silicon nitride film.

8. The method according to claim 7, wherein etching the silicon nitride film comprises dry etching the silicon nitride film using an etching gas, the etching gas comprising fluorohydrocarbons or an inert gas.

9. The method according to claim 8, further comprising removing etching reminders and copper reminders using a fluorine containing solution or an amine-based solution.

10. The method according to claim 1, further comprising forming a metallic diffusion stop layer on the second metal wiring.

11. The method according to claim 10, wherein the metallic diffusion stop layer comprises tungsten-cobalt (CoW).

12. A semiconductor device comprising:
a semiconductor substrate;
a first interlayer dielectric layer pattern, having a first trench, and a first via hole on the semiconductor substrate;
a metal wiring in the first trench and the first via hole and protruding the first interlayer dielectric layer pattern; and
a spacer on sides of the metal wiring protruding the first interlayer dielectric layer pattern.

13. The semiconductor device according to claim 12, wherein the metal wiring comprises copper.

14. The semiconductor device according to claim 12, wherein the metal wiring protrudes the first dielectric layer pattern by a thickness of about 50 Å to 2,000 Å.

15. The semiconductor device according to claim 12, further comprising a metallic diffusion stop layer on an upper surface of the metal wiring, and the metallic diffusion stop layer comprising tungsten-cobalt (CoW).
